(19) United States
(12) Patent Application Publication
(10) Pub. No.: US 2011/0006414 A1
(43) Pub. Date: Jan. 13, 2011

(54) ELECTRONIC DEVICE AND METHOD FOR MANUFACTURING ELECTRONIC DEVICE

(75) Inventor: Satoshi Ohara, Hachioji-shi (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/792,147

(22) Filed: Jun. 2, 2010

(30) Foreign Application Priority Data
Jul. 8, 2009 (JP) 2009-161908

(51) Int. Cl. H01L 23/48; B23K 37/00

(52) U.S. Cl. 257/734; 228/175; 257/E23.01

(57) ABSTRACT

An electronic device includes a semiconductor chip includes a functional area at a desired position and a board mechanically and electrically joined to the semiconductor chip board, with the board layered over the semiconductor chip. An electronic device includes at least one first joint member that joins the semiconductor chip and the board to each other and a second joint member that joins the semiconductor chip and the board to each other.

### CROSS-REFERENCE TO RELATED APPLICATIONS

This application is based upon and claims the benefit of priority from prior Japanese Patent Application No. 2009-161908, filed Jul. 8, 2009, the entire contents of which are incorporated herein by reference.

### BACKGROUND OF THE INVENTION

1. Field of the Invention

The present invention relates to an electronic device and a method for manufacturing an electronic device.

2. Description of the Related Art

For example, Jpn. Pat. Appln. KOKAI Publication No. 2005-303176 discloses a semiconductor device and a manufacturing method thereof. According to Jpn. Pat. Appln. KOKAI Publication No. 2005-303176, bumps are joint members (joints) between an electronic component (semiconductor chip) and a wiring board (carrier substrate). These bumps are provided between the electronic component and the wiring board, in plane directions of the electronic component and the wiring board, in order to distribute stress generated at outer peripheral parts of the electronic component.

The bumps are arranged radially from the center of the electronic component(wiring board)toward outer peripheral sides (outermost peripheral parts) thereof. Further, a bump provided in the center has a diameter different from that of a bump provided in the outer peripheral side. The sizes of the bumps gradually decrease from the outermost peripheral part toward the center.

This configuration suppresses differences in stress caused by differences in thermal expansion coefficient between individual members, such as the electronic component, wiring board, bumps, and sealing resin which seals a gap between the electronic component and the wiring board. This configuration accordingly prevents joint errors between the electronic component and the wiring board caused by concentrated stress.

### BRIEF SUMMARY OF THE INVENTION

According to an aspect of embodiments, an electronic device includes: a semiconductor chip comprising a functional area at a desired position; a board mechanically and electrically joined to the semiconductor chip board, with the board layered over the semiconductor chip; at least one first joint member that joins the semiconductor chip and the board to each other; and a second joint member that joins the semiconductor chip and the board to each other.

The present invention provides a method for manufacturing an electronic device, comprising: a first step that joins a semiconductor chip comprising a functional area at a desired position and a board to each other by a first joint member; and a second step that joins the semiconductor chip and the board to each other by a second joint member.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic view illustrating a configuration of an electronic device according to the first embodiment of the invention, viewed from a side of a semiconductor chip;

FIG. 2 is a view in which the configuration of FIG. 1 is cut along a line A-A;

FIG. 3 is an enlarged view of a periphery of a first joint member;

FIG. 4 is an enlarged view of a periphery of a second joint member;

FIG. 5A illustrates a state in which a functional area is surrounded by the first joint members;

FIG. 5B illustrates a state in which the functional area is not surrounded by the first joint member;

FIG. 6 is a schematic view illustrating a configuration of an electronic device according to the second embodiment of the invention, viewed from a side of a semiconductor chip;

FIG. 7 is a view in which the configuration of FIG. 6 is cut along a line B-B;

FIG. 8 is an enlarged view of a periphery of a first joint member;

FIG. 9 is an enlarged view of a periphery of a second joint member;

FIG. 10 is a table showing combinations of materials of the first and second joint members; and

FIG. 11 illustrates a modification to layout positions of the first joint members.

### DETAILED DESCRIPTION OF THE INVENTION

Hereinafter, an embodiment of the present invention will be described in details below.

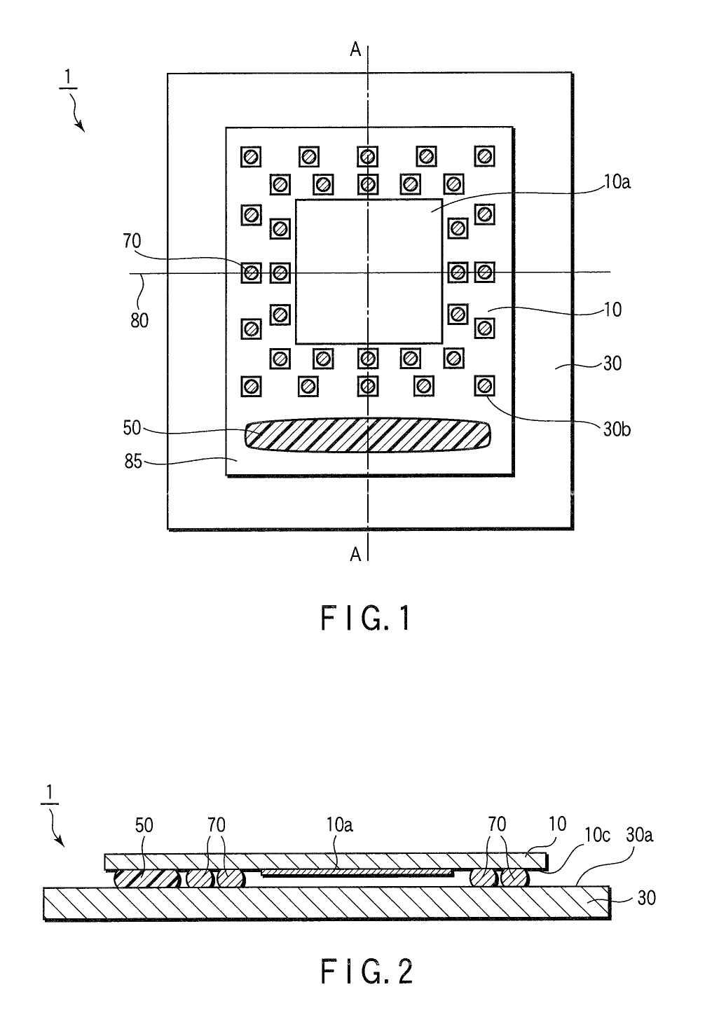

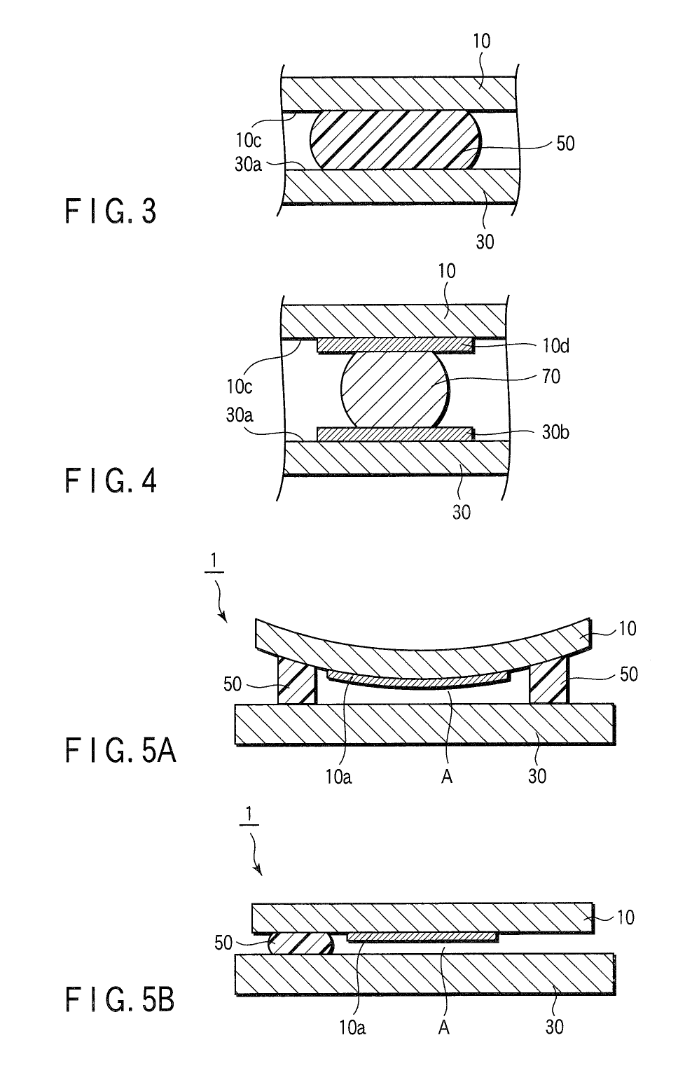

The first embodiment will now be described with reference to FIG. 1, FIG. 2, FIG. 3, FIG. 4, FIG. 5A, and FIG. 5B. To simplify the drawings, componential members are partially omitted from the drawings, for example, as joint pads 10d and 30b are omitted from FIG. 2.

As illustrated in FIG. 1, the electronic device 1 comprises: a semiconductor chip 10 which is an electronic component comprising an functional area 10a; a wiring board 30 which is layered over the semiconductor chip 10, thereby mechanically and is electrically joined to the semiconductor chip 10, and comprises a desired electronic wiring for the functional area 10a; and at least one first joint member 50 joining the semiconductor chip 10 and wiring board 30 to each other; and a second joint member 70 also joining the semiconductor chip 10 and wiring board 30 to each other. As illustrated in FIG. 2, the semiconductor chip 10 is layered over the wiring board 30 through the first joint member 50 and second joint member 70. The semiconductor chip 10 is provided to be layered over the wiring board 30, and is joined to the wiring board 30 through the first joint member 50 and the second joint member 70.

The semiconductor chip 10 is a plate-like member made of Si. The functional area 10a provided a desired position on the semiconductor chip 10, e.g., at for example, a center part in plane directions, and is opposed to the wiring board 30. Specifically, the functional area 10a is provided from inside of the semiconductor chip 10 toward a back surface 10c.

The wiring board 30 is a plate-like member made of SiO2, and is larger than the semiconductor chip 10.

Further, as illustrated in FIG. 4, planar joint pads 10d which hold and electrically join the semiconductor chip 10 to the wiring board 30 are provided at desired positions on the back surface 10c of the semiconductor chip 10.

Also as illustrated in FIG. 4, planar joint pads 30b which hold and electrically join the wiring board 30 to the semiconductor chip 10 are provided on a surface 30a of the wiring board 30. The joint pads 30b are provided to be opposed to the joint pads 10d.

As illustrated in FIG. 1, the joint pads 10d and joint pads 30b are provided so as to radially spread from the center part (functional area 10a) of the semiconductor chip 10 toward outer peripheral sides.

When the semiconductor chip 10 and wiring board 30 are layered, the second joint members 70 described above are provided between the joint pads 10d and the joint pads 30b. In this embodiment, if the second joint members 70 are, for example, solder as will described later, a Cr layer, a Ni layer, and an Au layer are layered on each of the joint pads 10d, in this order from the back surface 10c toward the surface 30a. Also, a CR layer, a Ni layer, and an Au layer are layered on each of the joint pads 30d, in this order from the surface 30a toward the back surface 10c.

The second joint member 70 is made of, for example, a metal material. If the metal material is, for example, solder, the solder is preferably eutectic low-melting solder of Sn/Bi. Materials of the joint pads 10d and joint pads 30b can be desirably changed depending on the second joint members 70. The second joint members 70 are, for example, made of a metal material, and therefore mechanically and electrically join the semiconductor chip 10 and the wiring board 30 to each other.

Further, in this embodiment, the first joint member 50 may be, for example, an adhesive agent made of resin (resin material), and may be conductive resin. The first joint member 50 is, for example, resin (resin material), and therefore mechanically join the semiconductor chip 10 to the wiring board 30.

Here, a layout position of the first joint member 50 will be described.

As illustrated in FIG. 1, on a planar coordinate system having an origin point which is a center point of the plane of the functional area 10a, the first joint member 50 is provided only in an area 85 which is one of two areas divided by a first line 80 extending through the origin point. In this embodiment, the first joint member 50 overlaps none of the joint pads 10d, joint pad 30b, and functional area 10a, but is linearly arranged closer to an outer peripheral side of the semiconductor chip 10 than the joint pads 10d and joint pads 30b. That is, first joint member 50 does not surround the functional area 10a but is provided to be opposed to the functional area 10a in a plane direction of the functional area 10a. At least one first joint member 50 may be provided.

Next, a relationship between materials of the first joint member 50 and the second joint members 70 will be described.

In this embodiment, the first joint member 50 have a softening point higher than a melting point of the second joint members 70. Therefore, if the second joint members 70 are made of solder, the first joint member 50 is, for example, an adhesive agent made of thermosetting resin which has a higher softening point than the melting point of the second joint members 70 (solder).

In this embodiment, the softening point is a temperature at which rigidity of resin changes greatly, such as a glass transition temperature or a vicat softening point. In this embodiment, however, the softening point is defined to be a glass transition temperature.

Next, a manufacturing method according to this embodiment will be described.

At first, a method for laying the semiconductor chip 10 over the wiring board 30 will be described.

As illustrated in FIG. 4, solder bumps as the second joint members 70 are manufactured on the joint pads 30b. In this embodiment, the solder bumps are manufactured by supplying a solder paste on the joint pads 30b, for example, in accordance with a supply method such as screen printing, and by heating the solder paste by a reflow.

Next, the wiring board 30 is applied with an adhesive agent made of resin to form the first joint members 50, for example, in accordance with an application method such as a dispensing method, as illustrated in FIG. 3.

The application method for the first joint member 50 and the supply method for the second joint members 70 are not limited to the methods described above. The application method may be, for example, screen printing or transfer coating. The supply method may be, for example, ball bumping or plating.

Further, an application amount of the first joint members 50 and a supply amount of the second joint members 70 are set to be greater by a desired amount than a gap amount between the semiconductor chip 10 and wiring board 30, in consideration of a gap between the semiconductor chip 10 and wiring board 30 after being mounted.

Next, a mounting process for mounting the semiconductor chip 10 on the wiring board 30 will be described.

In this embodiment, the mounting process is divided into first and second mounting processes.

The first mounting process will now be described first.

Of the semiconductor chip 10 and the wiring board 30, the semiconductor chip 10 is vacuum-suctioned and fixed to an upper stage of an unillustrated mounting machine, and the wiring board 30 is vacuum-suctioned and fixed to a lower stage of the unillustrated mounting machine. That is, the semiconductor chip 10 and the wiring board 30 are held by the mounting machine. At this time, the first joint members 50 are already applied to and the second joint member 70 is provided on the wiring board 30.

In this state, location accuracies of the semiconductor chip 10 and wiring board 30 are adjusted by an unillustrated adjustment section, on the basis of an image picked up by an imaging section such as a camera. Thereafter, the semiconductor chip 10 and the wiring board 30 are pre-heated at a desired temperature, for example, by an unillustrated heating section, such as a heater, through the upper stage and lower stage.

At this time, the desired temperature is higher than the melting point of the second joint members 70. That is, if the wiring board 30 is pre-heated, the second joint members 70 are then melted. In other words, to pre-heat the wiring board 30 is to melt the second joint members 70.

The desired temperature also maintains the first joint members 50 hardened before the semiconductor chip 10 and wiring board 30 are joined by the first joint member 50. That is, the first joint member 50 stays hardened even after pre-heating the wiring board 30. In other words, to pre-heat the wiring board 30 is to maintain the first joint members 50 hardened.

Thus, the desired temperature is a temperature higher than the melting point of the second joint members 70 and lower than the hardening temperature of the first joint member 50.

Thereafter, at least one of the upper stage and the lower stage moves closer to the other one so that the gap between the semiconductor chip 10 and the wiring board 30 agrees with a predetermined amount. When the upper stage and lower stage are positioned at desired positions, the semiconductor chip 10 and the wiring board 30 are then subjected to main heating at a desired temperature through the upper stage and lower stage by the heating section.

The desired temperature at this time is a temperature higher than the hardening temperature of the first joint members 50. The main heating is performed for a hardening time period for the first joint member 50. Next, together with the upper stage and lower stage, the semiconductor chip 10 and wiring board 30 are cooled to a desired temperature (lower than the melting point of the second joint members 70) for a desired time period by an unillustrated cooling section, and are thereby solidified. Accordingly, the first joint member 50 and the second joint members 70 are both cooled and solidified.

In this manner, the semiconductor chip 10 and wiring board 30 are mechanically joined to each other by the first joint member 50, and are mechanically and electrically joined to each other by the second joint members 70.

Next, the second mounting process will be described.

In a state after the first mounting process, the semiconductor chip 10 is held and joined by the mounting machine, and stress (deformation) remains acting on the semiconductor chip 10 due to the holding force, flatness of the upper stage, and/or dirt and foreign matters on a held interface of the semiconductor chip 10.

Hence, in the second mounting process, the semiconductor chip 10 and wiring board 30 which are electrically and mechanically joined to each other in the first mounting process are set in an unillustrated thermostat oven, and is reheated at a desired temperature. This desired temperature is a temperature higher than the melting point of the second joint members 70 and lower than a softening temperature of the first joint members 50.

In this manner, the second joint members 70 are remelted. At this time, the semiconductor chip 10 is released from joining forces of the second joint members 70, and only a joining force of the first joint member 50 acts on the semiconductor chip 10. That is, the semiconductor chip 10 and wiring board 30 are mechanically joined to each other by the first joint member 50. The second joint members 70 may be remelted between the first and second mounting processes (in other words, before the second mounting process) or during the second mounting process.

At this time, as illustrated in FIG. 5A, the semiconductor chip 10 is deformed by a joining force of the first joint members 50 if the functional area 10a which should not be deformed is sandwiched between fixed areas A formed by the first joint members 50 on a cross-sectional line A-A between the semiconductor chip 10 and wiring board 30 joined to each other.

However, as illustrated in FIG. 5B, in this embodiment, the functional area 10a which should not be deformed is not sandwiched between the fixed area A formed by the first joint member 50. Therefore, the semiconductor chip 10 is restricted from being deformed by the first joint members 50. That is, in this embodiment, the first joint member 50 is provided only on one of the areas 85. Through the first mounting process, the semiconductor chip 10 and the wiring board 30 are electrically and mechanically joined to each other by the first joint member 50 and the second joint members 70. The second joint members 70 are remelted through the second mounting process. In this manner, the semiconductor chip 10 is restricted (prevented) from being deformed.

Thereafter, on the semiconductor chip 10 which is not in contact with the other constitutional parts than the first joint member 50 and the second joint members 70 (i.e., the semiconductor chip 10 is not in contact with the other constitutional parts than the joint members 50 and 70), the second joint members 70 are subjected to natural cooling and solidified. In this manner, the semiconductor chip 10 is restricted from being deformed, and the semiconductor chip 10 which is mechanically joined to the wiring board 30 by the first joint member 50 is mechanically and electrically joined to the wiring board 30 by the second joint members 70. Further, the semiconductor chip 10 is mounted onto the wiring board 30, and the electronic device 1 is thereby formed.

Further, generation of deformation is prevented at this time, and stress (deformation) is therefore prevented. Accordingly, location accuracies of the electronic component (semiconductor chip 10) and the wiring board 30 are high.

Thus, the second mounting process has been suggested to be a process in which the second joint members 70 are remelted and thereafter mechanically and electrically join the semiconductor chip 10 and the wiring board 30 to each other.

Also, the second mounting process comprises a state (step) that the semiconductor chip 10 and the wiring board 30 are mechanically joined to each other only by the first joint members 50.

Also, the second mounting process comprises a state (step) that the second joint members 70 are temporarily remelted, before or during this process as described above, and a state (step) that the second joint members 70 are solidified after remelting of the second joint members 70, thereby to mechanically and electrically join the semiconductor chip 10 and wiring board 30 to each other by the second joint members 70.

Thus, in this embodiment, the electronic component (semiconductor chip 10) is restricted from being deformed after the first joint member 50 and second joint members 70 are joined to the semiconductor chip 10 and wiring board 30. Accordingly, there is provided an electronic device 1 capable of positioning the electronic component (semiconductor chip 10) and wiring board 30 with high accuracy.

Also in this embodiment, the first joint member 50 is provided only on one area 85 and the second joint members 70 are arranged radially, as described above. Also in this embodiment, the semiconductor chip 10 and wiring board 30 are joined to each other by the first joint member 50 and second joint members 70 through the first mounting process, and the second joint members 70 are remelted and solidified through the second mounting process. In this manner, in this embodiment, the semiconductor chip 10 is restricted from being deformed after the semiconductor chip 10 and wiring board 30 are joined to each other. Accordingly, the semiconductor chip 10 and wiring board 30 can be positioned with high accuracy.

Thus, in this embodiment, generation of deformation is restricted as described above, and therefore, the semiconductor chip 10 is not held by the mounting machine in the second mounting process. Positioning accuracies of the semiconductor chip 10 and wiring board 30 can be prevented from extreme deterioration when the semiconductor chip 10 and wiring board 30 are entirely mounted by heating.

Also in this embodiment, generation of deformation can be restricted when the semiconductor chip 10 is held by the mounting machine. Therefore, performance of the semiconductor chip 10 can be prevented from deterioration.

The layout positions and shape of the first joint members 50 are not particularly limited insofar as the first joint member 50 overlaps none of the joint pads 10d, joint pads 30b, and functional area 10a. The first joint member 50 may be provided, for example, closer to an inner peripheral side (a side of the functional area 10a) of the semiconductor chip 10 than the joint pads 10d and joint pads 30b. Also in this embodiment, the second joint members 70, first joint member 50, functional area 10a, and second joint members 70 may be provided in this order along the cross sectional line A-A in plane directions.

The electronic device 1 in this embodiment is, for example, a micro mirror device having an optical function.

Further, the first joint members 50 may have a curved shape or an arcuate shape.

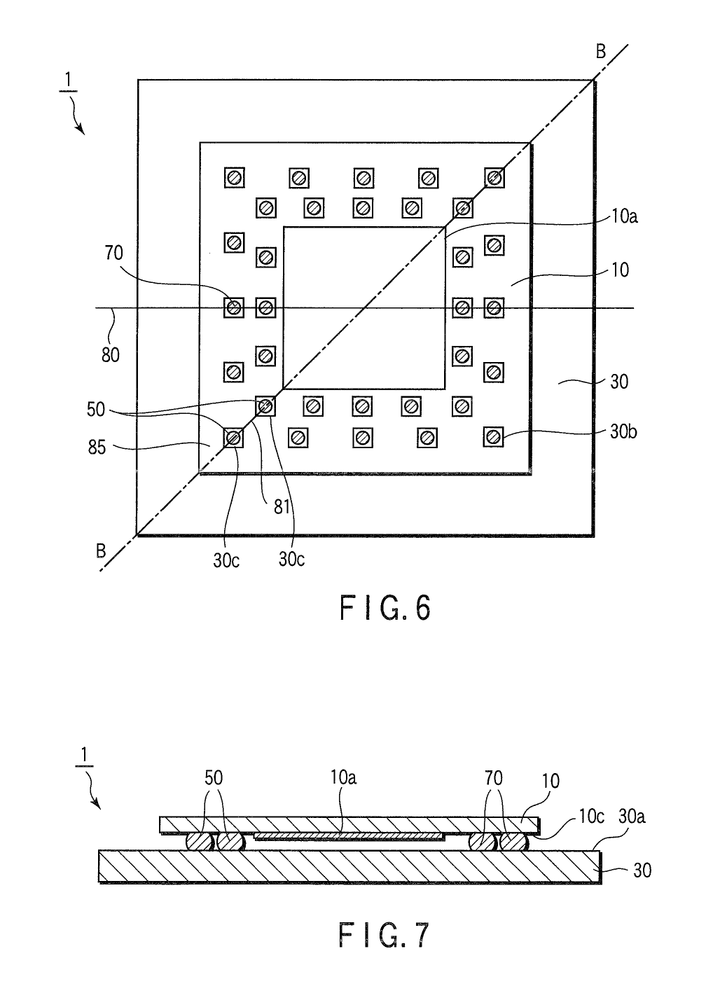

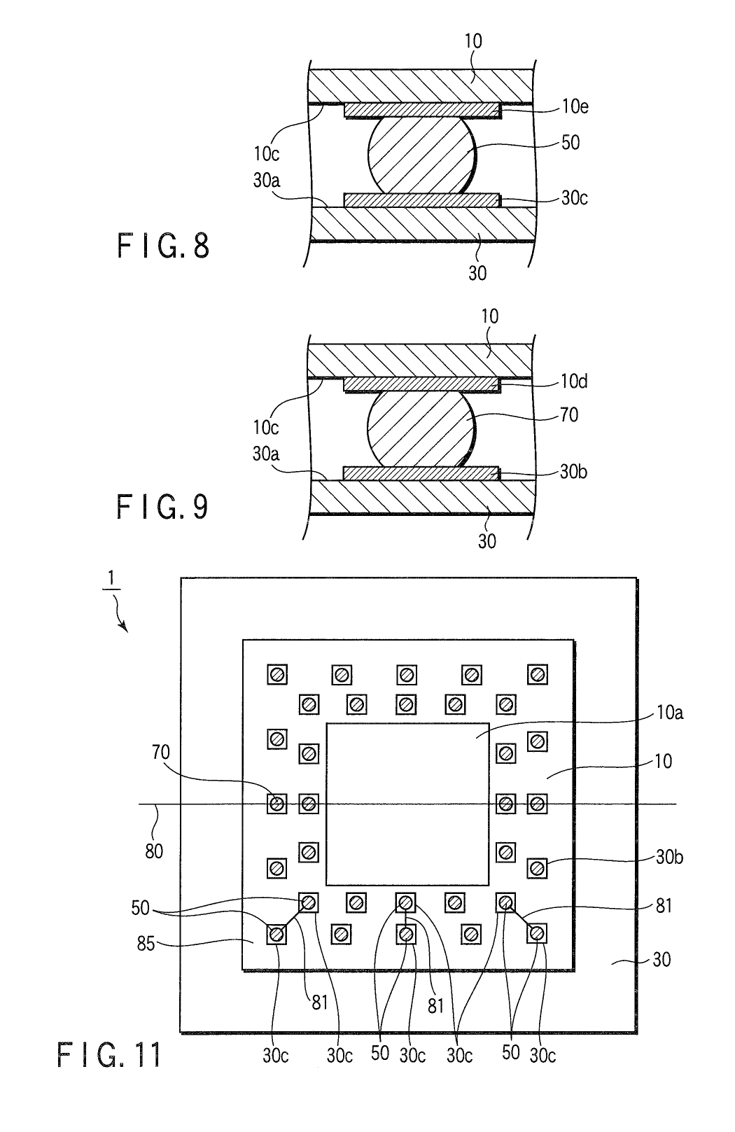

Next, the second embodiment will be described with reference to FIG. 6, FIG. 7, FIG. 8, and FIG. 9. The same portions as those in the first embodiment described above will be denoted at the same reference symbols, and detailed descriptions thereof will be omitted herefrom. To simplify the drawings, componential members are partially omitted from several drawings, for example, as joint pads 10d, 10e, 30b, and 30c are omitted from FIG. 7.

As illustrated in FIG. 8, the planar joint pads 10e which mechanically hold and join a semiconductor chip 10 to a wiring board 30 are provided at desired positions on a back surface 10c of the semiconductor chip 10 in this embodiment.

Also as illustrated in FIG. 8, the planar joint pads 30c which mechanically hold and join the wiring board 30 to the semiconductor chip 10 are provided on the surface 30a of the wiring board 30. The joint pads 30c are provided to be opposed to the joint pads 10e.

As illustrated in FIG. 8, when the semiconductor chip 10 and wiring board 30 are layered, first joint members 50 are provided between the joint pads 10e and the joint pads 30c. On the joint pads 10e, a Cr layer and an Au layer are layered in this order from the back surface 10c toward the a surface 30a. On the joint pads 30c each, an Al layer is formed. Two first joint members 50, two joint pads 10e, and two joint pad 30c are provided.

In this embodiment, the first joint members 50 and the second joint members 70 are, for example, metal materials. At this time, the material of the first joint members 50 has a melting point higher than that of the second joint member 70. The first joint members 50 are, for example, Au bumps, and the second joint members 70 are, for example, eutectic low-melting solder of Sn/Bi.

Here, layout positions of the first joint members 50 in this embodiment will be described.

On a planar coordinate system in which a center point of the plane of the functional area 10a is taken as an origin point, the first joint members 50 are provided on an area 85 as in the first embodiment. Further, second lines 81 each of which connects the first joint members 50 to each other in this embodiment are provided on lines at arguments of the first joint members 50 on the planar coordinate system. This second lines 81 are provided so as not to overlap the functional area 10a. In other words, the second lines 81 are provided between the functional area 10a and outer edges (circumference) of the semiconductor chip 10, in plane directions of the semiconductor chip 10, and do not cross the functional area 10a. That is, the first joint members 50 are provided on the second lines 81 each of which connects the first joint members 50 to each other, without overlapping the functional area 10a. Therefore, the two first joint members 50 do not sandwich the functional area 10a but are provided to be opposed to the functional area 10a in the plane directions of the functional area 10a.

Next, a manufacturing method according to this embodiment will be described.

At first, a method for layering the semiconductor chip 10 on the wiring board 30 will be described.

As illustrated in FIG. 9, solder bumps (eutectic low-melting solder of Sn/Bi) as the second joint members 70 are manufactured on the joint pads 30b, in the same manner as in the first embodiment. Further, Au bumps as the first joint members 50 are provided (manufactured) on the joint pads 30c, as illustrated in FIG. 8. Used as the Au bumps are stud bumps which are joined to the joint pads 30c by performing ultrasonic joining on Au balls after forming the Au balls from parts of a line of melted Au on the joint pads 30c. The method for manufacturing the Au bumps is not limited to the method described above but may alternatively be, for example, plating.

As in the first embodiment, a supply amount of the first joint members 50 and a supply amount of the second joint members 70 are set to be greater by a desired amount than a gap amount between the semiconductor chip 10 and the wiring board 30, in consideration of a gap between the semiconductor chip 10 and wiring board 30 after being mounted.

Next, a mounting process of mounting the semiconductor chip 10 onto the wiring board 30 will be described.

In this embodiment, the mounting process is divided into first and second mounting processes.

The first mounting process will be described first.

Of the semiconductor chip 10 and the wiring board 30, the semiconductor chip 10 is vacuum-suctioned and fixed to an upper stage of an unillustrated mounting machine, and the wiring board 30 is vacuum-suctioned and fixed to a lower stage of the unillustrated mounting machine. That is, the semiconductor chip 10 and the wiring board 30 are held by the mounting machine. At this time, the first joint members 50 and the second joint members 70 are provided on the wiring board 30, as described above.

In this state, location accuracies of the semiconductor chip 10 and wiring board 30 are adjusted by an unillustrated adjustment section, on the basis of an image picked up by an imaging section such as a camera. Thereafter, the semiconductor chip 10 and the wiring board 30 are pre-heated at a desired temperature, for example, by an unillustrated heating section, such as a heater, through the upper stage and lower stage.

Thereafter, at least one of the upper stage and the lower stage moves closer to the other one so that the gap between the semiconductor chip 10 and the wiring board 30 agrees with a predetermined amount. When the upper stage and lower stage are positioned at desired positions, the semiconductor chip 10 and the wiring board 30 are then subjected to main heating at a desired temperature through the upper stage and lower stage by the heating section. Next, the semiconductor chip 10 and the wiring board 30 are pressed under a desired pressure through the upper stage and the lower stage by an unillustrated pressure section. In this manner, the first joint members 50 and the joint pads 10e are subjected to solid-state diffusion bonding translation to each other.

The main heating and the pressing are performed for a time period through which solid-state diffusion bonding translation is completed between the first joint members 50 and the joint pads 10e. Then, the semiconductor chip 10 and the wiring board 30, together with the upper stage and lower stage, are cooled to a desired temperature for a desired time period by an unillustrated cooling section, and are thereby solidified. Accordingly, the first joint members 50 and second joint members 70 are both cooled and solidified.

In this manner, the semiconductor chip 10 and wiring board 30 are mechanically joined to each other by the first joint members 50, and are mechanically and electrically joined to each other by the second joint member 70.

Before joining the semiconductor chip 10 and the wiring board 30, for example, obstacles which may hinder the joining may be removed from surfaces of the first joint members 50 and the joint pads 10e by, for example, plasma cleaning. If the plasma cleaning is performed, the first joint members 50 and the joint pads 10e can be subjected to solid-state diffusion bonding translation at a lower temperature.

Next, the second mounting process will be described.

As in the first embodiment, in a state after the first mounting process, the semiconductor chip 10 is held and joined by the mounting machine, and stress (deformation) remains acting on the semiconductor chip 10 due to the holding force thereof, flatness of the upper stage, and/or dirt and foreign matters on a holding interface of the semiconductor chip 10.

Hence, in the second mounting process, the semiconductor chip 10 and wiring board 30 which are electrically and mechanically joined to each other in the first mounting process are set in an unillustrated thermostat oven, and is reheated at a desired temperature. This desired temperature is a temperature higher than the melting point of the second joint members 70 and lower than a melting point of the first joint members 50.

In this manner, the second joint members 70 are remelted. At this time, the semiconductor chip 10 is released from a joining force of the second joint members 70, and only a joining force of the first joint members 50 acts on the semiconductor chip 10. That is, the semiconductor chip 10 and wiring board 30 are mechanically joined to each other by the first joint members 50. The second joint member 70 may be remelted between the first and second mounting processes or during the second mounting process.

At this time, as in the first embodiment, the semiconductor chip 10 is deformed by a joint force of the first joint members 50 if the functional area 10a which should not be deformed is sandwiched between fixed areas A formed by the first joint members 50.

However, in this embodiment, the functional area 10a which should not to be deformed is not sandwiched between the fixed areas A formed by the first joint members 50. Therefore, the semiconductor chip 10 is restricted from being deformed by the first joint members 50. That is, in this embodiment, the first joint members 50 are provided only on one of the areas 85 and on the second lines 81. Through the first mounting process, the semiconductor chip 10 and the wiring board 30 are electrically and mechanically joined to each other by the first joint members 50 and the second joint members 70. The second joint members 70 are remelted through the second mounting process. In this manner, the semiconductor chip 10 is restricted (prevented) from being deformed.

Further, in this embodiment, stress caused by joining forces from the first joint members 50 is prevented from being transmitted to the functional area 10a by providing the first joint members 50.

Thereafter, on the semiconductor chip 10 which is not in contact with the other constitutional parts than the first joint members 50 and the second joint members 70 (i.e., the semiconductor chip 10 is not in contact with the other constitutional parts than the joint members 50 and 70), the second joint members 70 are subjected to natural cooling and solidified. In this manner, the semiconductor chip 10 is restricted from being deformed, and the semiconductor chip 10 which is mechanically joined to the wiring board 30 by the first joint members 50 is mechanically and electrically joined to the wiring board 30 by the second joint members 70. Further, the semiconductor chip 10 is mounted onto the wiring board 30, and the electronic device 1 is thereby formed.

Further, generation of deformation is prevented at this time, and positional errors are therefore prevented. Accordingly, location accuracies of the electronic component (semiconductor chip 10) and the wiring board 30 are high.

Thus, in this embodiment, the same advantages as in the first embodiment can be attained.

Further, in this embodiment, stress caused by a joint force from the first joint members 50 is prevented from being transmitted to the functional area 10a by providing the first joint members 50.

Also in this embodiment, Au bumps are used as the first joint members 50, and deterioration of sealing performance can be therefore more prevented when the electronic device 1 is sealed in a reduced-pressure atmosphere or an inactive atmosphere, compared with resin materials.

Also in this embodiment, the second lines 81 are provided as diagonals of the semiconductor chip 10, and are not limited to such diagonals. For example, the second lines 81 may be provided at desired inclinations so as not to overlap the functional area 10a without penetrating through the origin point (the center point on the functional area 10a). Further, the number of first joint members 50 is not limited.

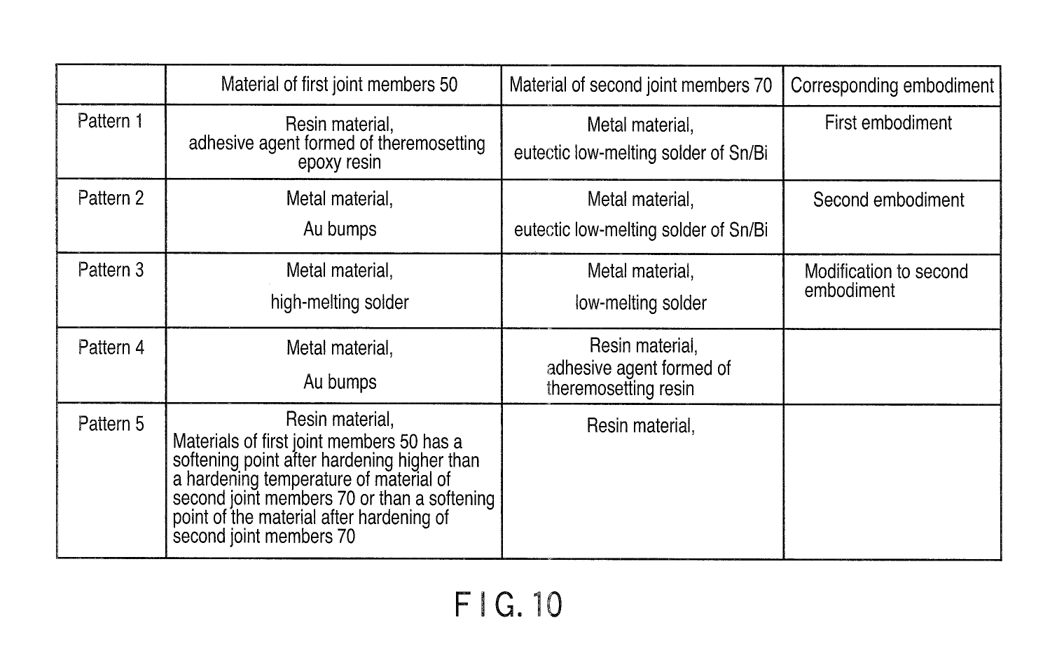

In each of the embodiments described above, materials of the first joint members 50 and the second joint members 70 need not be limited to materials described above. FIG. 10 shows patterns of combinations between those materials.

Pattern 1 shows the first embodiment described above. Pattern 2 shows the second embodiment described above.

Pattern 3 shows a modification to the second embodiment described above.

In Pattern 3, the first joint members 50 and the second joint members 70 are both made of metal materials, and the material of the first joint members 50 has a melting point higher than the material of the second joint members 70. The first joint members 50 are, for example, high-melting solder which has a high melting point. The second joint members 70 are, for example, low-melting-point solder which has a lower melting point than the first joint members 50.

Pattern 4

For example, the first joint members 50 are a metal material, and the second joint members 70 are a resin material. In this case, the melting point of the material of the first joint members 50 need only be higher than at least one of a hardening temperature of the material of the second joint members 70 and a softening point of the material of the second joint members 70 after hardening. The first joint members 50 are, for example, Au bumps, and the second joint members 70 are, for example, an adhesive agent made of resin, or more specifically an adhesive agent made of thermosetting resin.

If Pattern 4 is employed, the second mounting process comprises a step of temporarily thermosetting the second joint members 70 before or during the second mounting process, thereby to join the semiconductor chip 10 and the wiring board 30 to each other by the second joint members 70.

Pattern 5

The first joint members 50 and second joint members 70 are both resin materials. In this case, the softening point after hardening of the material of the first joint members 50 is higher than the hardening temperature of the material of the second joint members 70 or is higher than the softening point after hardening of the material of the second joint members 70. That is, the first joint members 50 are a material, the softening point of which after hardening is higher than the hardening temperature of the material of the second joint members 70 or is higher than the softening point of the material after hardening of the second joint members 70.

Further, in each of the embodiments described above, layout positions of the first joint members 50 are not limited to the positions described above. For example, as illustrated in FIG. 11, the first and second embodiments may be combined with each other. For example, the first joint members 50 are provided only on the area 85. Further, the first joint members 50 do not overlap the functional area 10a but are provided on the second line 81 which connect the first joint members 50 to each other. In FIG. 11, the first joint members 50 are arranged radially but need not be limited to this arrangement. Insofar as the second lines 81 do not overlap the functional area 10a, the first joint members 50 may be provided in parallel along an edge of the functional area 10a or the semiconductor chip 10.

In descriptions made above, the second joint members 70, joint pads 10d, and joint pads 30b are provided so as to radially spread from the center part (functional area 10a) of the semiconductor chip 10 toward outer peripheral sides. However, this is not a limitative configuration insofar as the second joint members 70 can electrically join the semiconductor chip 10 and the wiring board 30 to each other.

The present invention is not limited to the embodiments as exactly described above but can be embodied with modifications applied thereto in practical phases, without deviating from the subject matters of the invention. Further, various invention can be derived from appropriate combinations of plural constitutional elements disclosed in the embodiments described above.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic device comprising:
a semiconductor chip comprising a functional area at a desired position;
a board mechanically and electrically joined to the semiconductor chip board, with the board layered over the semiconductor chip;
at least one first joint member that joins the semiconductor chip and the board to each other; and
a second joint member that joins the semiconductor chip and the board to each other.

2. The electronic device of claim 1, wherein
the first joint member comprises a resin material,
the second joint member comprises a metal material, and
the first joint member has a softening point higher than a melting point of the second joint member.

3. The electronic device of claim 1, wherein
the first joint member and the second joint member comprise a metal material, and
the first joint member has a melting point higher than a melting point of the second joint member.

4. The electronic device of claim 1, wherein
the first joint member comprises a metal material,
the second joint member comprises a resin material, and
the first joint member has a melting point higher than at least one of a hardening point of the second joint member, and a softening point after hardening of the second joint members.

5. The electronic device of claim 1, wherein
the first joint member and the second joint member comprise a resin material, and
the first joint member has a melting point after hardening, which is higher than a hardening temperature of the second joint member, or is higher than a softening point after hardening of the second joint members.

6. The electronic device of claim 1, wherein
on a planar coordinate system having an origin point which is a center point of a plane of the functional area, the at least one first joint member is provided in one of two areas divided by a line extending through the origin point.

7. The electronic device of claim 6, wherein
a line connecting the first joint members to each other is arranged so as not to overlap the functional area on the planar coordinate system.

8. The electronic device of claim 7, wherein
the line connecting the first joint members to each other is arranged on a line at an argument of the first joint members, on the planar coordinate system.

9. A method for manufacturing an electronic device, comprising:
a first step that joins a semiconductor chip comprising a functional area at a desired position and a board to each other by a first joint member; and
a second step that joins the semiconductor chip and the board to each other by a second joint member.

10. The method of claim 9, wherein the second step comprises a step in which the semiconductor chip and the board are joined to each other by the first joint member.

11. The method of claim 10, wherein
the second step comprises:
a step that temporarily remelts the second joint member before or during the second; and
a step that solidified the second joint member after the second joint member is remelted, and joins the semiconductor chip and the board to each other by the second joint member.

12. The method of claim 11, wherein
the second step comprises a step in which the semiconductor chip is not in contact with any other constitutional part than the first and second joint members.

13. The method of claim 10, wherein
the second step comprises a step that temporarily hardeneds the second joint member by heating before or during the second step, thereby to join the semiconductor chip and the board to each other by the second joint member.

14. The method of claim 13, wherein
the second step comprises a step in which the semiconductor chip is not in contact with any other constitutional part than the first and second joint members.

15. The method of claim 10, wherein
the second step comprises a step in which the semiconductor chip is not in contact with any other constitutional part than the first and second joint members.

16. The method of claim 9, wherein
the second step comprises:
a step that temporarily remelts the second joint member before or during the second; and
a step that solidified the second joint member after the second joint member is remelted, and joins the semiconductor chip and the board to each other by the second joint member.

17. The method of claim 16, wherein
the second step comprises a step in which the semiconductor chip is not in contact with any other constitutional part than the first and second joint members.

18. The method of claim 9, wherein
the second step comprises a step that temporarily hardeneds the second joint member by heating before or during the second step, thereby to join the semiconductor chip and the board to each other by the second joint member.

19. The method of claim 18, wherein
the second step comprises a step in which the semiconductor chip is not in contact with any other constitutional part than the first and second joint members.

20. The method of claim 9, wherein
the second step comprises a step in which the semiconductor chip is not in contact with any other constitutional part than the first and second joint members.
